(19) United States
(12) Patent Application Publication
(10) Pub. No.: US 2025/0167041 A1
(43) Pub. Date: May 22, 2025

(54) BEOL INTEGRATION SOLUTION BASED ON DIRECT CMP TO IMPROVE INTERMETAL DIELECTRIC LAYER

(71) Applicant: STMicroelectronics International N.V., Geneva (CH)

(72) Inventors: Fabrizio Fausto Renzo TOIA, Busto Arsizio (IT); Daniele CAPELLI, Basiano (IT); Samuele SCIARRILLO, Usmate Velate (IT)

(73) Assignee: STMicroelectronics International N.V., Geneva (CH)

(21) Appl. No.: 18/516,501

(22) Filed: Nov. 21, 2023

(51) Int. Cl. H01L 21/768; H01L 23/528

(52) U.S. Cl. CPC H01L 21/76819; H01L 21/76837; H01L 21/7685; H01L 21/76885; H01L 23/528

(57) ABSTRACT

A process that helps ensure uniform height of conductive structures formed among intermetal dielectric layers of a wafer. When a metal layer is deposited on a first intermetal dielectric layer, a sealing layer is formed on the metal layer either before or after the metal layer is patterned to form metal interconnect structures. A first interlevel dielectric sub-layer is then formed on the sealing layer. A chemical mechanical planarization (CMP) process is then performed on the first interlevel dielectric sub-layer using the sealing layer as an etch stop. A second interlevel dielectric sub-layer is then formed on the first interlevel dielectric sub-layer.

### BACKGROUND

### Technical Field

The present disclosure relates to integrated circuit processing, and, more particularly, to backend-of-line (BEOL) process.

### Description of the Related Art

BEOL processes based involve the formation of metal lines and metal interconnect structures of integrated circuits after transistors have been formed. An integrated circuit may include several metal layers e.g., metal 1, metal 2, etc. among intermetal dielectric layers. For example, an intermetal dielectric layer may be formed over the transistors of an integrated circuit. A first metal layer (e.g., metal 1) may be formed on the intermetal dielectric layer. The metal layer may then be patterned to form first metal interconnect structures. A second intermetal dielectric layer may then be formed on the first intermetal dielectric layer and the first metal interconnect structures. Conductive vias may be formed in the second intermetal dielectric layer to contact the first metal interconnect structures. A second metal layer (e.g., metal 2) may then be formed on the second intermetal dielectric layer. The second metal layer may then be patterned to form second metal interconnect structures.

However, there are various problems that can occur during BEOL processing. For example, during processing of a wafer, the height of dielectric layers or the height of conductive vias may vary based on distance from the center of the wafer. In other words, some structures may have a different height for integrated circuits near center of a wafer than for integrated circuits at the edge of the wafer.

All of the subject matter discussed in the Background section is not necessarily prior art and should not be assumed to be prior art merely as a result of its discussion in the Background section. Along these lines, any recognition of problems in the prior art discussed in the Background section or associated with such subject matter should not be treated as prior art unless expressly stated to be prior art. Instead, the discussion of any subject matter in the Background section should be treated as part of the inventors' approach to the particular problem, which, in and of itself, may also be inventive.

### BRIEF SUMMARY

Embodiments of the present disclosure provide a process that helps ensure uniform height of conductive structures formed among intermetal dielectric layers of a wafer. When a metal layer is deposited on a first intermetal dielectric layer, a sealing layer is formed on the metal layer either before or after the metal layer is patterned to form metal interconnect structures. A first interlevel dielectric sub-layer is then formed on the sealing layer. A chemical mechanical planarization (CMP) process is then performed on the first interlevel dielectric sub-layer using the sealing layer as an etch stop. A second interlevel dielectric sub-layer is then formed on the first interlevel dielectric sub-layer.

Because the sealing layer is utilized as an etch stop for the CMP process, the second interlevel dielectric sub-layer has a uniform height above the metal interconnect structures. The result is that subsequently formed conductive vias in the second interlevel dielectric sub-layer have a uniform height throughout the entirety of the wafer. The first and second interlevel dielectric sub-layers collectively form a second intermetal dielectric layer.

In one embodiment, a method includes forming a transistor, forming a first intermetal dielectric layer above the transistor, forming a metal stack on the first intermetal dielectric layer, and patterning the metal stack to form metal lines on the first intermetal dielectric layer. The method includes forming a sealing layer on the tops and sidewalls of the metal lines and on the exposed surface of the first intermetal dielectric layer between the metal lines, forming a first intermetal dielectric layer on the sealing layer between the metal lines and above the metal lines, and performing a CMP process on the first intermetal dielectric layer including using the sealing layer as an etch stop layer to stop the CMP process.

In one embodiment, a method includes forming a transistor, forming a first intermetal dielectric layer above the transistor, forming a metal stack on the first intermetal dielectric layer, and forming a sealing layer on a top of the metal stack. The method includes patterning the sealing layer and the metal stack to form a plurality of metal lines from the metal stack with the sealing layer on the metal lines, forming a first intermetal dielectric layer between the metal lines and on the sealing layer above the metal lines, and performing a CMP process on the first intermetal dielectric layer including using the sealing layer as an etch stop layer to stop the CMP process.

In one embodiment, an integrated circuit includes a transistor, a first intermetal dielectric layer above the transistor, and a plurality of metal lines on the first intermetal dielectric layer. The integrated circuit includes a dielectric sealing layer on the metal lines, a second intermetal dielectric layer on the first intermetal dielectric layer and on the sealing layer and having a top surface substantial equidistant from a top of each of the metal lines, a conductive via in the second intermetal dielectric layer and in contact with one of the metal lines.

In one embodiment, a method includes forming a transistor, forming a first intermetal dielectric layer above the transistor, forming a plurality of metal lines with a sealing layer covering at least a top of each metal line, forming a first intermetal dielectric sub-layer between the metal lines and on the sealing layer above the metal lines, and performing a CMP process on the first intermetal dielectric sub-layer including using the sealing layer as an etch stop layer to stop the CMP process.

In one embodiment, an integrated circuit includes a first intermetal dielectric layer, a first metal line on the first intermetal dielectric layer, and a second metal line on the first intermetal dielectric layer. The integrated circuit includes a sealing layer continuously covering top surfaces and sidewalls of the first and second metal lines and the top surface of the first intermetal dielectric layer between the first and second metal lines. The integrated circuit includes a second intermetal dielectric layer on the sealing layer above and between the first and second metal lines.

### BRIEF DESCRIPTION OF THE SEVERAL VIEWS OF THE DRAWINGS

FIGS. 1A-1H are cross-sectional views of a wafer at various stage of processing, in accordance with one embodiment.

FIGS. 2A-2G are cross-sectional views of a wafer at various stage of processing, in accordance with one embodiment.

FIG. 3 is a top view of a wafer, in accordance with one embodiment.

FIG. 4 is a flow diagram of a method for forming an integrated circuit, in accordance with one embodiment.

FIG. 5 is a flow diagram of a method for forming an integrated circuit, in accordance with one embodiment.

### DETAILED DESCRIPTION

In the following description, certain specific details are set forth in order to provide a thorough understanding of various disclosed embodiments. However, one skilled in the relevant art will recognize that embodiments may be practiced without one or more of these specific details, or with other methods, components, materials, etc. In other instances, well-known systems, components, and circuitry associated with integrated circuits have not been shown or described in detail, to avoid unnecessarily obscuring descriptions of the embodiments.

Unless the context requires otherwise, throughout the specification and claims which follow, the word “comprise” and variations thereof, such as, “comprises” and “comprising” are to be construed in an open, inclusive sense, that is as “including, but not limited to.” Further, the terms “first,” “second,” and similar indicators of sequence are to be construed as interchangeable unless the context clearly dictates otherwise.

Reference throughout this specification to “one embodiment” or “an embodiment” means that a particular feature, structure, or characteristic described in connection with the embodiment, is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

As used in this specification and the appended claims, the singular forms “a,” “an,” and “the” include plural referents unless the content clearly dictates otherwise. It should also be noted that the term “or” is generally employed in its broadest sense, that is as meaning “and/or” unless the content clearly dictates otherwise.

As used herein, the terms “intermetal dielectric layer” and “interlevel dielectric layer” may be used synonymously.

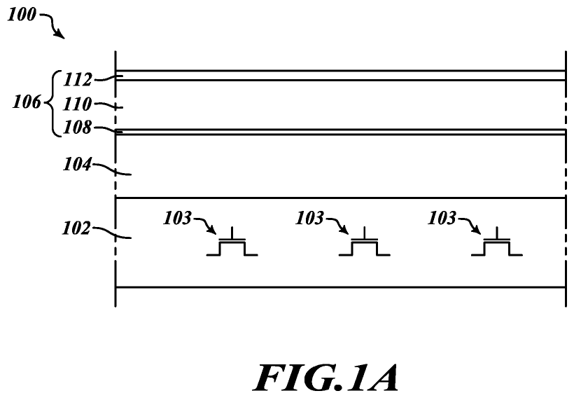

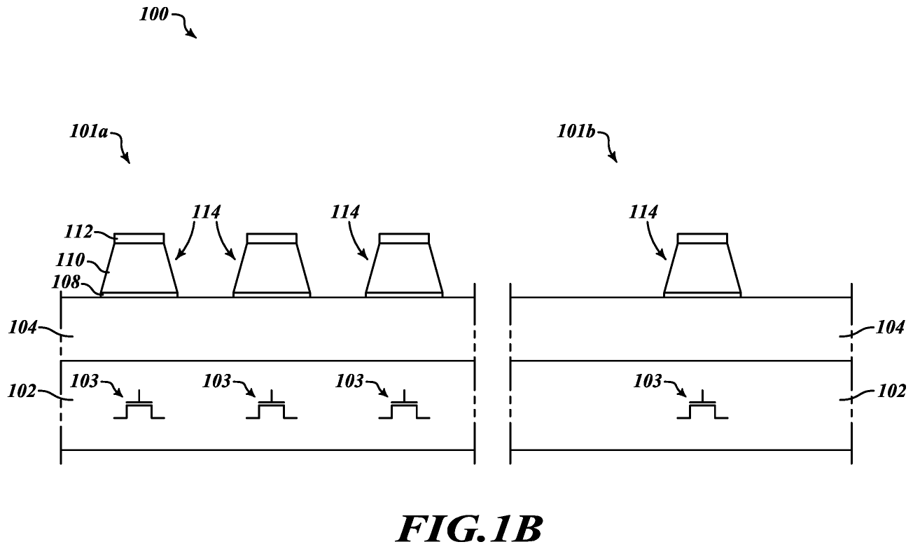

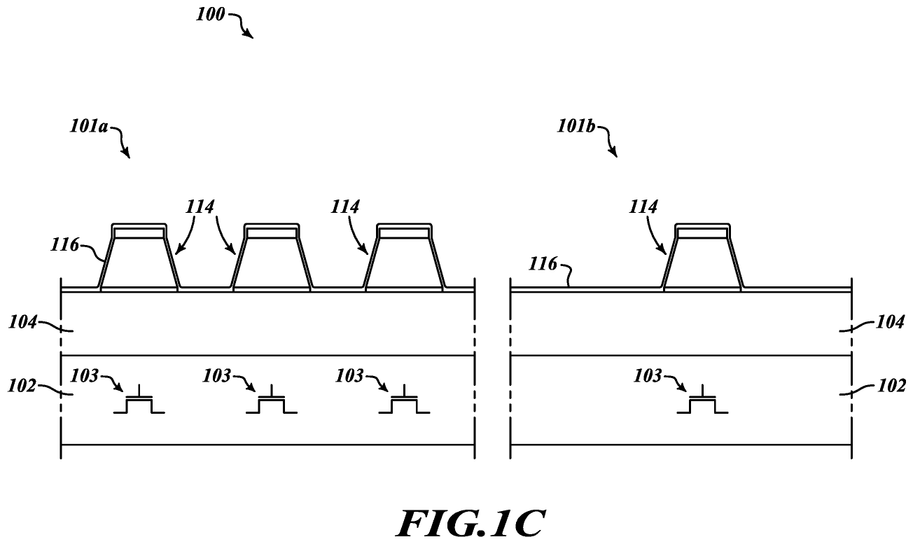

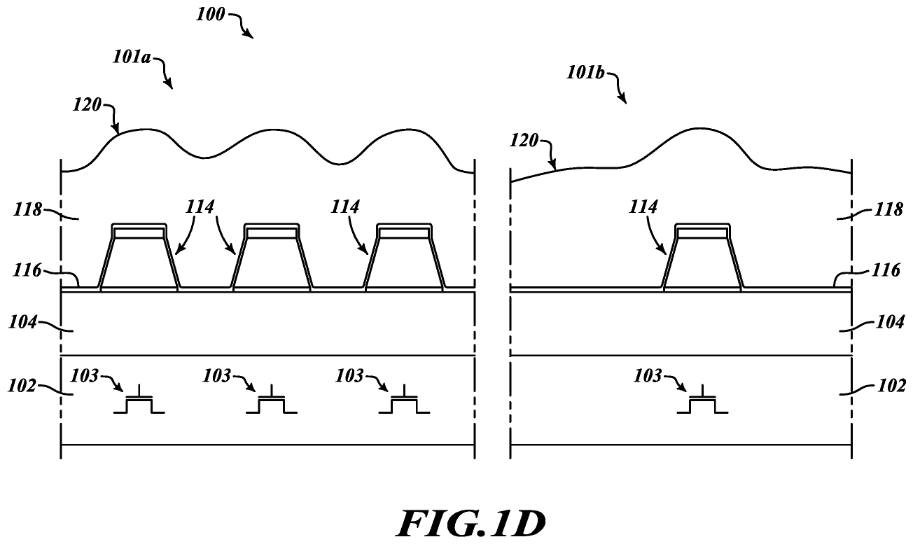

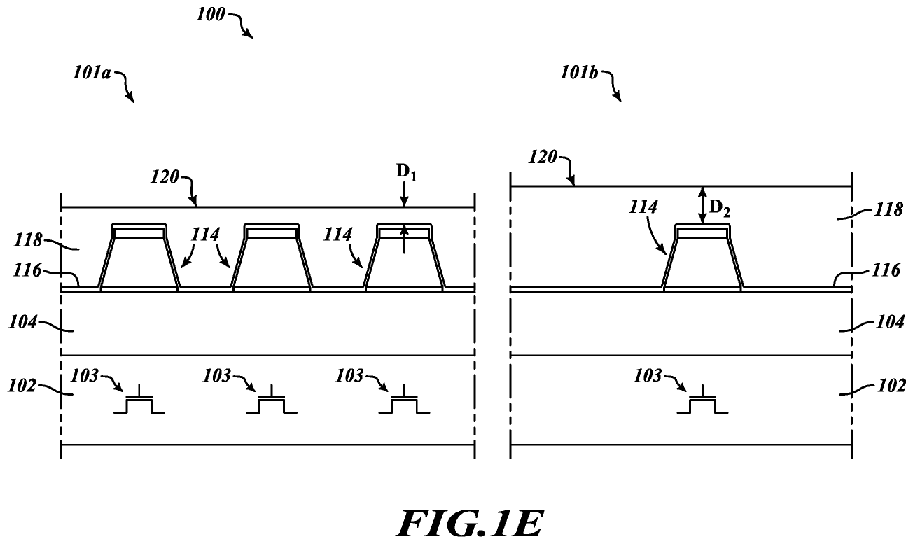

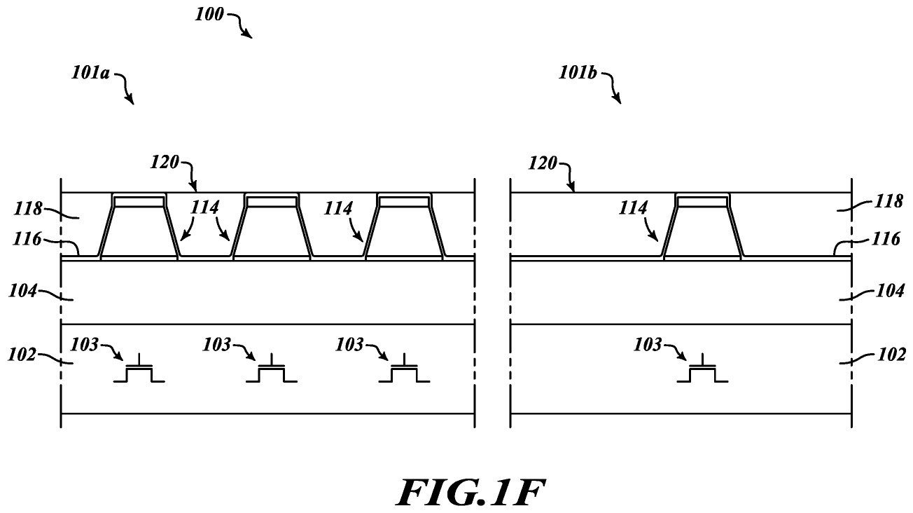

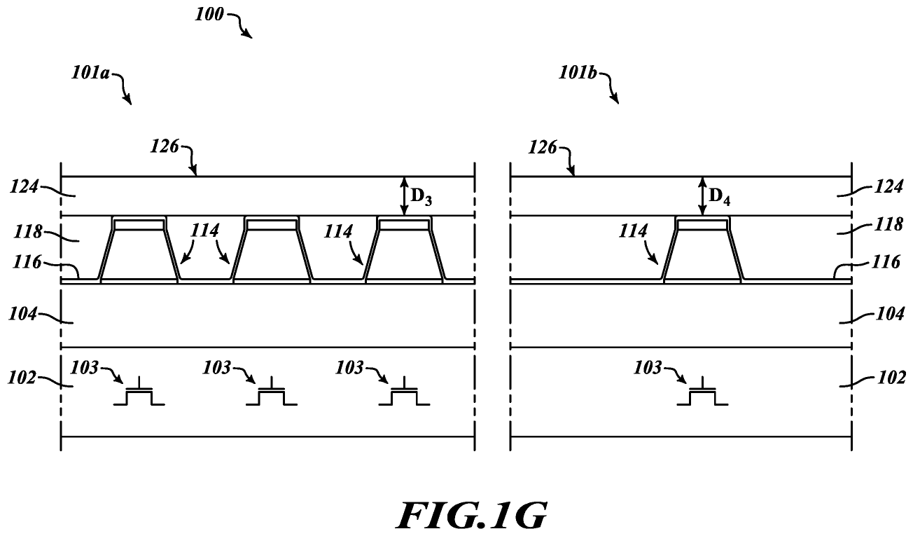

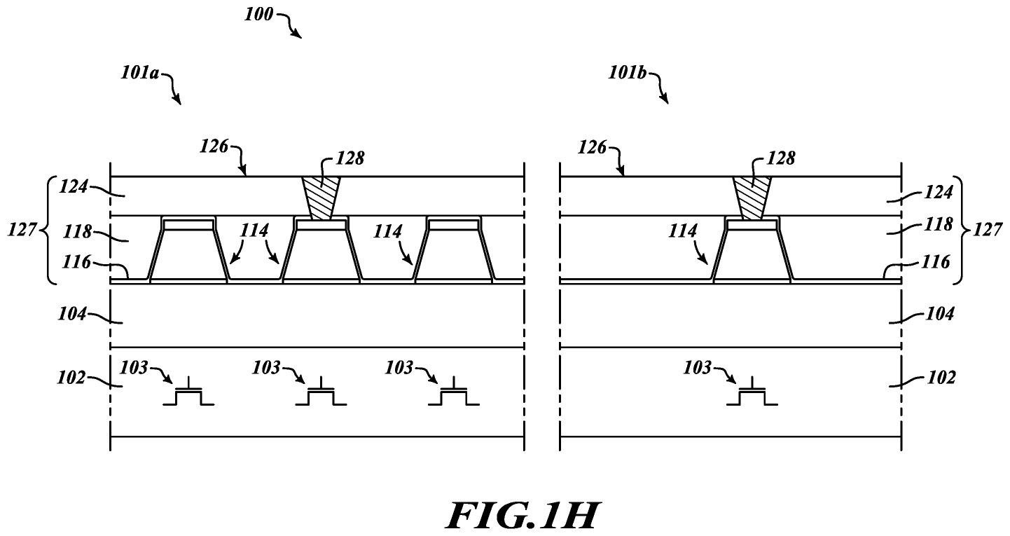

FIG. 1A is a cross-sectional view of a wafer 100 at an intermediate stage of processing, in accordance with one embodiment. Processing of the wafer 100 will result in a plurality of substantially identical integrated circuits.

In FIG. 1A, the wafer 100 includes a substrate 102. A plurality of transistors 103 have been formed in conjunction with the substrate 102. Although the substrate 102 is shown as a single layer, in practice, the substrate 102 may include a plurality of layers.

The substrate 102 can include a semiconductor layer. The semiconductor layer may include a plurality of semiconductor layers or a semiconductor heterostructure. A portion of the transistors 103 may be formed the semiconductor layer.

In one embodiment, the transistors 103 are high electron mobility transistors (HEMTs). In one example, the transistors 103 are GaN transistors. Alternatively, the transistors can include CMOS transistors.

In one embodiment, the substrate 102 includes silicon. However, the substrate 102 can include other types of semiconductor materials. In some embodiments, the substrate 102 may include one or more layers of dielectric material. The substrate 102 can include other materials suitable for forming an HEMT.

In the example of an HEMT, the substrate 102 may include a base layer of silicon, a layer of aluminum nitride on the silicon, and a buffer layer on the layer of aluminum nitride. A semiconductor heterostructure, including the buffer layer, may be formed on the layer of aluminum nitride. The semiconductor heterostructure can include a channel layer of the HEMT. The semiconductor heterostructure can also include other layers. In the example of a GaN HEMT transistor, the channel layer, or other layers of the semiconductor heterostructure may include GaN. The HEMT can include source and drain regions and a gate region. Other configurations of an HEMT can be utilized without departing from the scope of the present disclosure.

Front end of line (FEOL) can include the processing steps utilized to form the transistors 103. After the FEOL processing, middle end of line (MEOL) processing can include processing steps between formation of the transistors 103 and formation of a first metal layer.

In FIG. 1A, a first intermetal dielectric layer 104 has been formed over the transistors 103. In one embodiment, the first intermetal dielectric layer 104 includes silicon oxide. However, the interlevel dielectric layer 104 can include materials other than silicon oxide without departing from the scope of the present disclosure. The first intermetal dielectric layer 104 can include a plurality of layers of dielectric material.

In FIG. 1A, a metal layer 106 has been formed on the interlevel dielectric layer 104. The metal layer 106 corresponds to a first metal layer of BEOL processing. Accordingly, the metal layer 106 may correspond to metal 1. Alternatively, the metal layer 106 can correspond to a higher metal layer.

In one embodiment, the metal layer 106 is a stack of metal layers. For example, the metal layer 106 can include a metal layer 108 on the intermetal dielectric layer 104, a metal layer 110 on the metal layer 108, and a metal layer 112 on the metal layer 110. In one embodiment, the metal layer 108 includes titanium, the metal layer 110 includes AlCu, and the metal layer 112 includes titanium nitride. Alternatively, other metal materials can be utilized for the layers 108, 110, and 112 without departing from the scope of the present disclosure.

In one embodiment, the metal layer 108 has a thickness between 5-20 nm. The metal layer 110 is a thickness between 200 nm and four micrometers, and the metal layer 112 is a thickness between 5-50 nm. Other thicknesses can be utilized without departing from the scope of the present disclosure.

FIG. 1B illustrates the wafer 100 including a first region 101a and a second region 101b. The first region 101a and the second region 101b may be part of a same integrated circuit of the wafer 100 or a different integrated circuits of the wafer 100. In FIG. 1B, a photolithography processes been performed to pattern the metal layer 106. The patterning of the metal layer 106 results in the formation of metal interconnect structures 114 on the intermetal dielectric layer 104. Accordingly, the metal interconnect structures 114 are formed from the metal layer 106. The metal interconnect structures 114 may be metal lines or other types of metal interconnect structures. The first region 101a is a region of dense interconnect structure formation. In other words, a plurality of metal interconnect structures 114 are positioned adjacent to each other in the first region 101a. The second region 101b corresponds to a region in which there is sparse formation of metal interconnect structures. Only a single metal interconnect structure 114 is shown in the second region 101b.

In FIG. 1C, a sealing layer 116 has been deposited. In particular, the sealing layer 116 has been conformally deposited on the exposed portions of the top surface of the intermetal dielectric layer 104, on sidewalls of the metal interconnect structures 114, and on top surfaces of the metal interconnect structures 114. In one embodiment, the sealing layer includes a dielectric material such as silicon nitride. The sealing layer 116 may have a thickness between 50 nm and 700 nm, preferably 50-500 nm. Other materials and thicknesses can be utilized for the sealing layer 116 without departing from the scope of the present disclosure. As will be set forth in more detail below, the sealing layer 116 will be utilized as an etch stop layer for a CMP process. Alternatively, the sealing layer can include SiCN, AlN, Al2O3, HfO2, or HfxAlyOz.

The deposition of the sealing layer 116 on all exposed surfaces of the metal interconnect structures 114 and the top surface of the intermetal dielectric layer 104 can be beneficial because it is possible that there can be metal residue on the intermetal dielectric layer 104 from the patterning of the metal interconnect structures. Deposition of the sealing layer 116 on the intermetal dielectric layer 104 can help isolate the possible metal residues, which in absence of the continuous sealing layer 116 could cause electrical problems or electric arcing.

In FIG. 1D, a first intermetal dielectric sub-layer 118 has been formed on the sealing layer 116 between above the metal interconnect structures 114. As can be seen in FIG. 1D, the first intermetal dielectric sub-layer 118 has a non-planar top surface 120. Furthermore, the first interlevel dielectric sub-layer 118 has a different thickness above the metal interconnect structures 114 in the region 101a and the metal interconnect structure 114 in the region 101b. The first intermetal dielectric sub-layer 118 can include silicon oxide or another suitable dielectric material.

In FIG. 1E, a first CMP step of a CMP process has been performed. The first CMP step is a timed CMP step that rapidly etches the X 118. The first CMP step stops prior to reaching the sealing layer 116. The first CMP step utilizes a first slurry having an etch chemistry that rapidly etches the first intermetal dielectric sub-layer 118. As can be seen in FIG. 1E, the top surface 120 has a different height dimension D1 above the metal interconnect structures 114 of the region 101a than the height dimension D2 of the top surface 120 above the metal interconnect structure 114 in the region 101b.

In FIG. 1F, a second CMP step of the CMP process has been performed. The second CMP step uses a second slurry that is different than the first slurry. The second CMP step etches more slowly than the first CMP step. The second CMP step utilizes the sealing layer 116 as an etch stop. Accordingly, the CMP process stops upon encountering the sealing layer 116 on the tops of the metal interconnect structures 114. As can be seen in FIG. 1F, the top surface 120 of the first intermetal dielectric sub-layer 118 is planar. Alternatively, a single CMP process can be performed.

In FIG. 1G, a second intermetal dielectric sub-layer 124 has been deposited on the first intermetal dielectric sub-layer 118. The second intermetal dielectric sub-layer 124 can include silicon oxide or another suitable dielectric material. The first intermetal dielectric sub-layer 118 and the second intermetal dielectric sub-layer 124 collectively make up a second intermetal dielectric layer 127. Although a boundary is shown between the first intermetal dielectric sub-layer 118 and the second intermetal dielectric sub-layer 124, in practice, the interface between the first intermetal dielectric sub-layer 118 and the second intermetal dielectric sub-layer 124 may be indistinguishable as the first intermetal dielectric sub-layer 118 and the second intermetal dielectric sub-layer 124 are the same material. The second intermetal dielectric sub-layer 124 can be deposited by chemical vapor deposition (CVD) or by atomic layer deposition (ALD).

The top surface 126 of the second intermetal dielectric sub-layer 124 has a height D3 above the metal interconnect structures 114 at the region 101a. The top surface 126 of the second intermetal dielectric sub-layer 124 has a height dimension D4 above the metal interconnect structure 114. D3 and D4 are the same. In other words, the top surface 126 of the second intermetal dielectric sub-layer 124 is a same height above all of the metal interconnect structures 114. More particularly, the height of the top surface 126 of the second intermetal dielectric sub-layer 124 is the same above the metal interconnect structures 114 at all regions of a wafer 100 without performing an additional CMP process. In FIG. 1H, conductive vias 128 have been formed in the second intermetal dielectric sub-layer 124. In particular, an etching process has been performed to etch through the second intermetal dielectric sub-layer 124 and the sealing layer 116 above selected metal interconnect structures 114. This exposes the tops of the metal interconnect structures 114. A conductive via 128 can then be formed in each of the openings as shown in FIG. 1H. The conductive via can be formed by depositing a conductive material such as tungsten, titanium, aluminum, copper, or other conductive materials in the openings. A CMP process can then be performed to remove excess conductive material from the top of the interlevel dielectric layer 127.

The conductive vias 128 have a same height in all areas of the wafer 100. This is a result of the use of the sealing layer 116 is an etch stop as described previously. This can help enhance alignment of conductive vias with metal interconnect structures 114. This process can be performed for each metal layer of the wafer 100.

Formation of the intermetal dielectric layer 127 and the conductive vias 128 in the manner described above results in many advantages. The uniformity of dielectric thickness is improved compared to other possible solutions. Furthermore there is better wafer to wafer and lot to lot uniformity of intermetal dielectric layers as removal rate is not a key factor of the second CMP step due to the use of the sealing layer 116 is an etch stop. Furthermore, the resistance of conductive vias 128 is improved and made more uniform. This results in improved electrical characteristics and performance of integrated circuits.

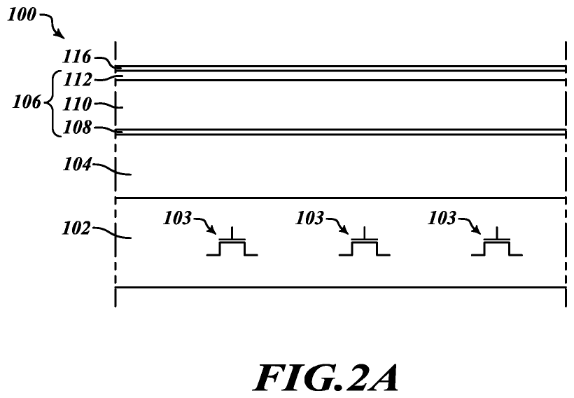

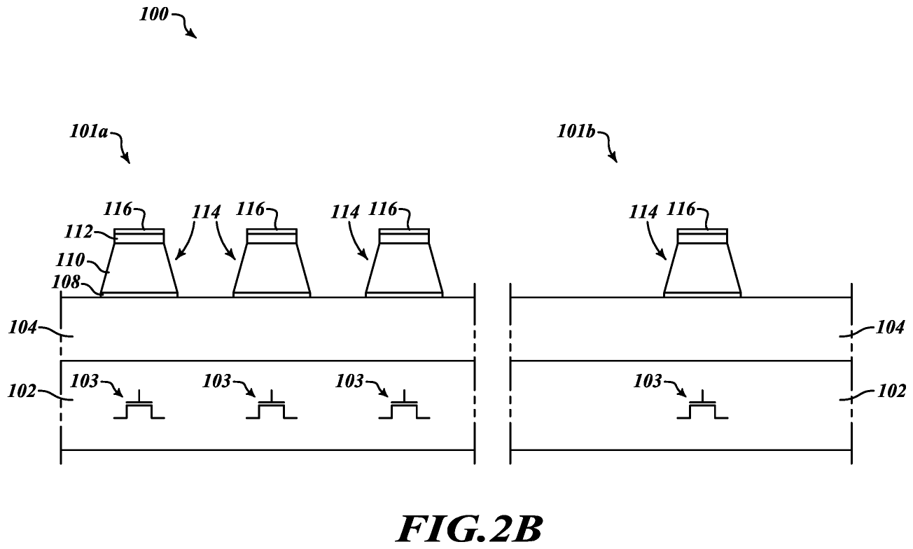

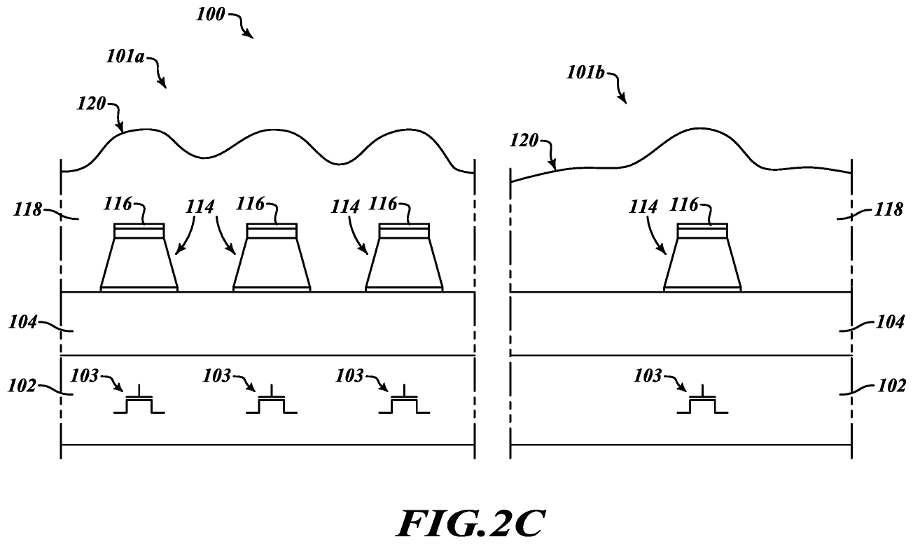

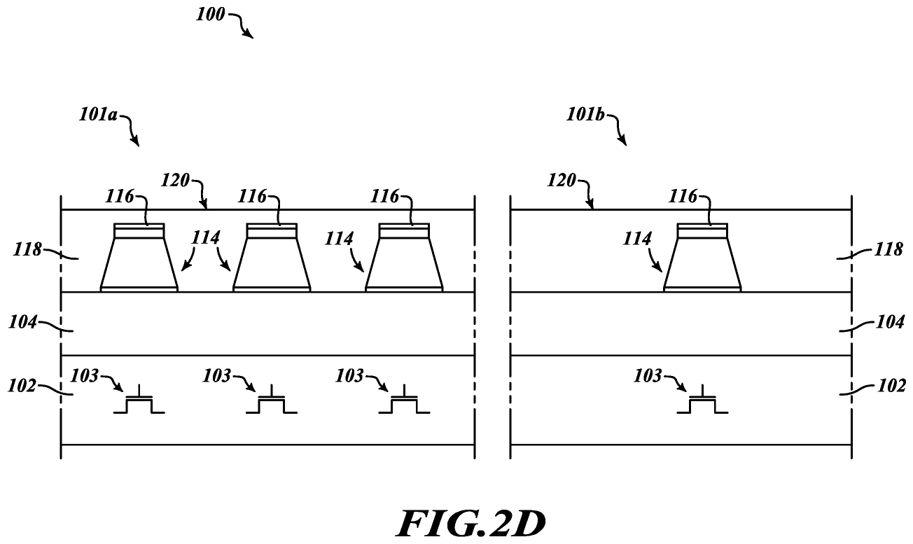

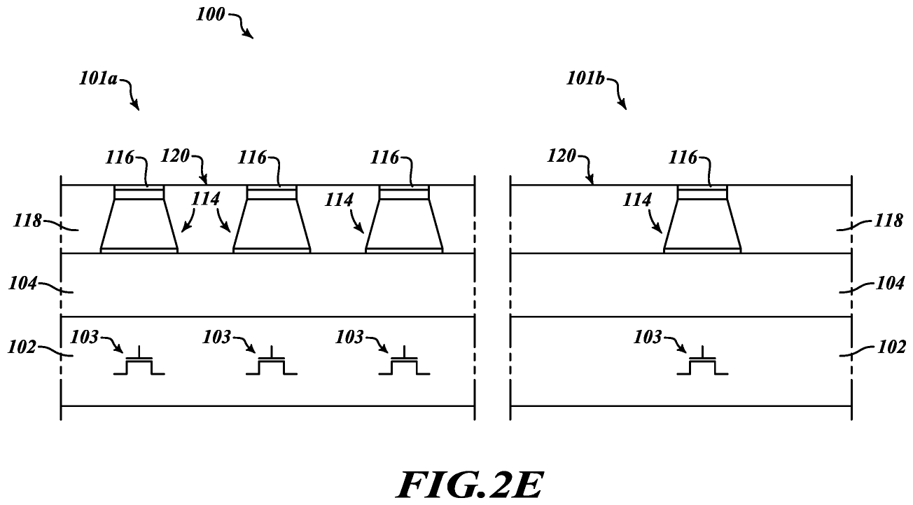

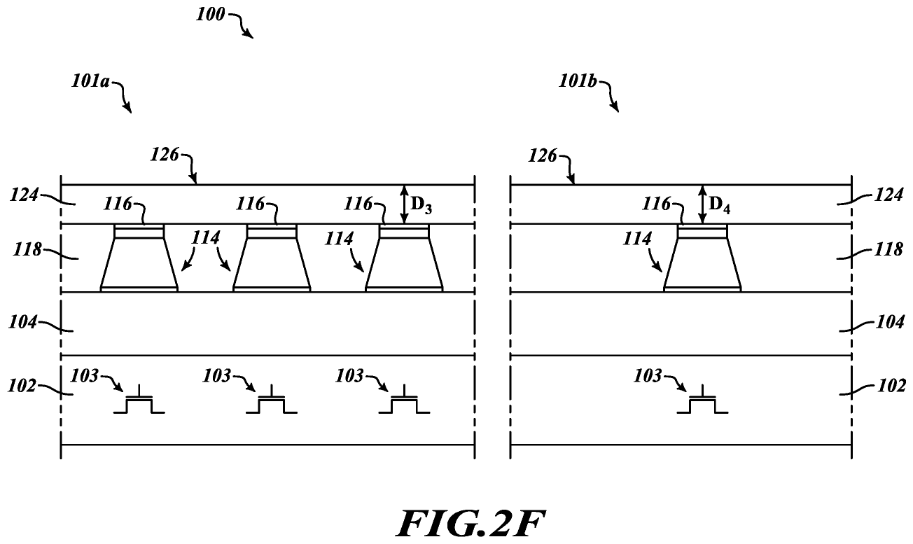

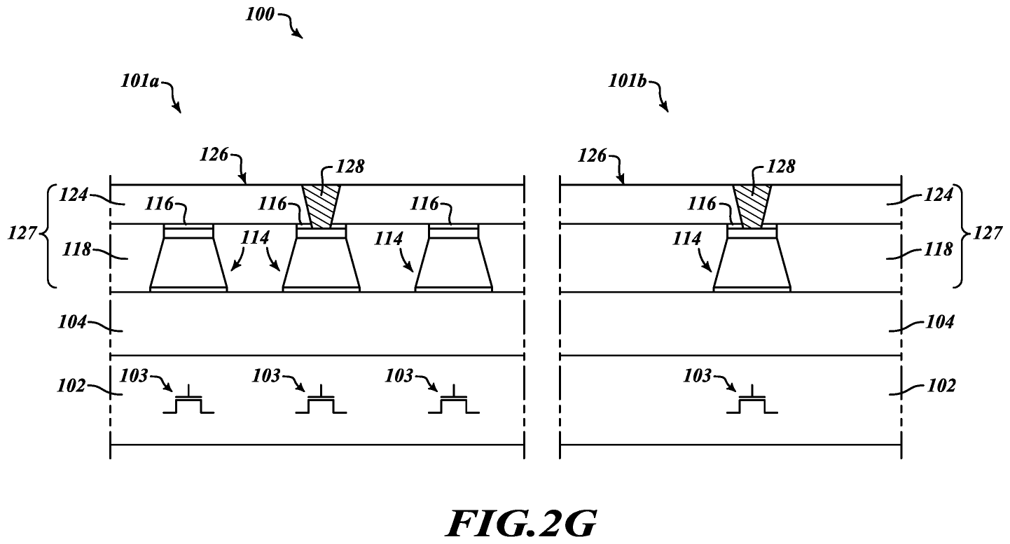

FIGS. 2A-2F are cross-sectional views of a wafer 100 and intermediate stages of processing, in accordance with one embodiment. In FIG. 2A, the substrate 102, the transistors 103, the intermetal dielectric layer 104, and the metal layer 106 have been formed substantially as described in relation to FIG. 1A. However, the wafer 100 of FIG. 2A differs from the wafer 100 of FIG. 1A in that the sealing layer 116 has been deposited on the metal layer 106 prior to patterning the metal layer 106. The sealing layer 116 can be formed substantially as described in relation to FIG. 1C.

In FIG. 2B, the metal layer 106 has been patterned to form metal interconnect structures 114, as described in relation to FIG. 1B. However, in FIG. 2B the patterning of the metal layer 106 also includes patterning the sealing layer 116. The sealing layer 116 is not positioned on the sidewalls of the metal interconnect structures 114 or on the top surface of the intermetal dielectric layer 104 in FIG. 2B. The sealing layer 116 is only on the top surfaces of the metal interconnect structures 114.

In FIG. 2C, the first intermetal dielectric sub-layer 118 has been deposited substantially as described in relation to FIG. 1D. In FIG. 2C, the first intermetal dielectric sub-layer 118 is in contact with sidewalls of the metal interconnect structures 114 and the exposed top surface of the intermetal dielectric layer 104.

In FIG. 2D, a first CMP step of a CMP process has been performed to reduce the height of the top surface 120 of the first intermetal dielectric sub-layer 118. The first CMP step is performed substantially as described in relation to FIG. 1E. Although not apparent in FIG. 2D, the top surface 120 may have a different height dimension above the metal interconnect structures 114 of the region 101a compared to the metal interconnect structures 114 of the region 101b.

In FIG. 2E, a second CMP step of the CMP process has been performed using the sealing layer 116 is an etch stop. Accordingly, the top surface 120 of the of the first intermetal dielectric sub-layer 118 is substantially coplanar with the top surface of the sealing layer 116. The second CMP step of the CMP process can be performed substantially as described in relation to FIG. 1F.

In FIG. 2F, the second intermetal dielectric sub-layer 124 has been formed. The second intermetal dielectric sub-layer 124 can be formed substantially as described in relation to FIG. 1G. The second intermetal dielectric sub-layer 124 has a uniform height above the metal interconnect structures 114 at all regions of the wafer 100.

In FIG. 2G, conductive vias 128 have been formed in the second intermetal dielectric sub-layer 124 connecting with selected metal interconnect structures 114. The conductive vias 128 can be formed can be formed substantially as described in relation to FIG. 1H. The conductive vias 128 have a uniform height for all regions of the wafer 100.

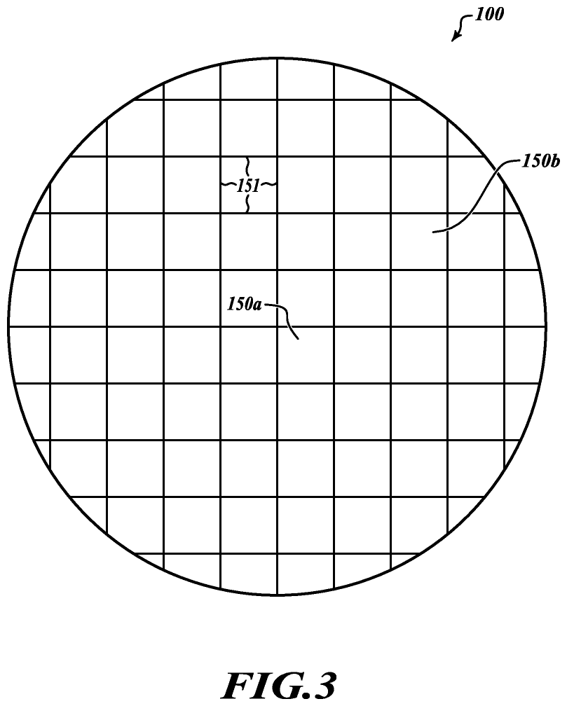

In FIG. 3 is a top view of a wafer 100, in accordance with one embodiment. The wafer 100 is one example of a wafer 100 of FIGS. 1A-1F. The wafer 100 includes a plurality of integrated circuits 150. An integrated circuit 150a is positioned near a center of the wafer 100. An integrated circuit 150b is positioned near an edge of the wafer 100. Utilizing the processes described in relation to FIGS. 1A-2F, intermetal dielectric layers of conductive vias will have uniform height and thicknesses for the integrated circuit 150a near the center of the wafer 100 and the integrated circuit 150b near the edge of the wafer 100. FIG. 3 also illustrates scribe lines 151. After processing of the wafer 100 is complete, the wafer 100 is diced along the scribe lines 151 two singulate the integrated circuits 150.

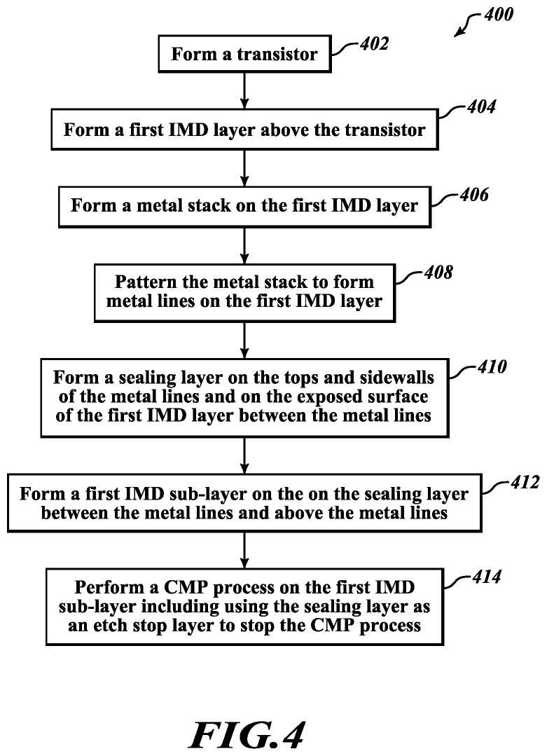

FIG. 4 is a flow diagram of a method 400 for forming an HEMT, in accordance with one embodiment. The method 400 can utilize processes, structures, and systems described in relation to FIGS. 1A-2F. At 402, the method 400 includes forming a transistor. At 404, the method 400 includes forming a first intermetal dielectric layer above the transistor. At 406, the method 400 includes forming a metal stack on the first intermetal dielectric layer. At 408, the method 400 includes patterning the metal stack to form metal lines on the first intermetal dielectric layer. At 410, the method 400 includes forming a sealing layer on the tops and sidewalls of the metal lines and on the exposed surface of the first intermetal dielectric layer between the metal lines. At 412, the method 400 includes forming a first intermetal dielectric layer on the sealing layer between the metal lines and above the metal lines. At 414, the method 400 includes performing a CMP process on the first intermetal dielectric layer including using the sealing layer as an etch stop layer to stop the CMP process.

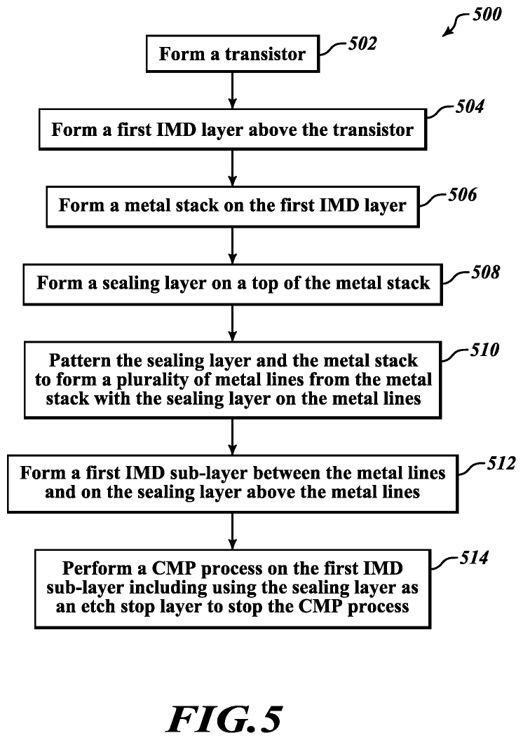

FIG. 5 is a flow diagram of a method 500 for forming an HEMT, in accordance with one embodiment. The method 500 can utilize processes, structures, and systems described in relation to FIGS. 1A-2F. At 502, the method 500 includes forming a transistor. At 504, the method 500 includes forming a first intermetal dielectric layer above the transistor. At 506, the method 500 includes forming a metal stack on the first intermetal dielectric layer. At 508, the method 500 includes forming a sealing layer on a top of the metal stack. At 510, the method 500 includes patterning the sealing layer and the metal stack to form a plurality of metal lines from the metal stack with the sealing layer on the metal lines. At 512, the method 500 includes forming a first intermetal dielectric layer between the metal lines and on the sealing layer above the metal lines. At 514, the method 500 includes performing a CMP process on the first intermetal dielectric layer including using the sealing layer as an etch stop layer to stop the CMP process.

In one embodiment, a method includes forming a transistor, forming a first intermetal dielectric layer above the transistor, forming a metal stack on the first intermetal dielectric layer, and patterning the metal stack to form metal lines on the first intermetal dielectric layer. The method includes forming a sealing layer on the tops and sidewalls of the metal lines and on the exposed surface of the first intermetal dielectric layer between the metal lines, forming a first intermetal dielectric layer on the sealing layer between the metal lines and above the metal lines, and performing a CMP process on the first intermetal dielectric layer including using the sealing layer as an etch stop layer to stop the CMP process.

In one embodiment, performing the CMP process includes performing a first CMP step corresponding to a timed CMP step and performing a second CMP step after the time CMP step including using the sealing layer as the etch stop.

In one embodiment, the first CMP step includes using a first slurry, wherein the second CMP step includes using a second slurry different from the first etch chemistry.

In one embodiment, the method includes depositing a second intermetal dielectric layer on the first intermetal dielectric layer. The second intermetal dielectric layer has a top surface that is substantially planar without CMP. The first intermetal dielectric layer and the second intermetal dielectric layer collectively form a second intermetal dielectric layer. As used herein, the term “substantially planar” can mean that an actual thickness value of the second intermetal dielectric sub-layer varies less than +/−5% from a nominal thickness value. For example, the nominal thickness value is X nm and the actual thickness value is 0.95*X and 1.05*X.

In one embodiment, the method includes exposing a top surface of one of the metal lines by forming a trench in the second intermetal dielectric layer and forming a conductive via in the trench in contact with the top surface of the metal line.

In one embodiment, a first distance between a top surface of a first one of the metal lines and a top surface of the second intermetal dielectric layer is substantially the same as a distance between a top surface of a second one of the metal lines and the top surface of the second intermetal dielectric layer center. The first one of the metal lines is in an integrated circuit near a center of a wafer, wherein the second one of the metal lines in a second integrated circuit near an edge of the wafer.

In one embodiment, the first intermetal dielectric layer is silicon oxide and the sealing layer is silicon nitride.

In one embodiment, a method includes forming a transistor, forming a first intermetal dielectric layer above the transistor, forming a metal stack on the first intermetal dielectric layer, and forming a sealing layer on a top of the metal stack. The method includes patterning the sealing layer and the metal stack to form a plurality of metal lines from the metal stack with the sealing layer on the metal lines, forming a first intermetal dielectric layer between the metal lines and on the sealing layer above the metal lines, and performing a CMP process on the first intermetal dielectric layer including using the sealing layer as an etch stop layer to stop the CMP process.

In one embodiment, the method includes depositing a second intermetal dielectric layer on the first intermetal dielectric layer.

In one embodiment, the second intermetal dielectric layer has a top surface that is substantially planar without CMP.

In one embodiment, the first intermetal dielectric layer and the second intermetal dielectric layer collectively form a second intermetal dielectric layer.

In one embodiment, the method includes exposing a top surface of one of the metal lines by forming a trench in the second intermetal dielectric layer and the sealing layer and forming a conductive via in the trench in contact with the top surface of the metal line.

In one embodiment, an integrated circuit includes a transistor, a first intermetal dielectric layer above the transistor, and a plurality of metal lines on the first intermetal dielectric layer. The integrated circuit includes a dielectric sealing layer on the metal lines, a second intermetal dielectric layer on the first intermetal dielectric layer and on the sealing layer and having a top surface substantial equidistant from a top of each of the metal lines, a conductive via in the second intermetal dielectric layer and in contact with one of the metal lines.

In one embodiment, the second intermetal dielectric layer includes the second intermetal dielectric layer includes a first intermetal dielectric layer having a top surface substantially coplanar with a top surface of the sealing layer and a second intermetal dielectric layer on the first intermetal dielectric layer.

In one embodiment, the first and second intermetal dielectric layers are of a same material.

In one embodiment, the transistor is a GaN transistor.

In one embodiment, the sealing layer is on sidewalls of the first metal lines and on a top surface of the first intermetal dielectric layer between the metal lines and the second intermetal dielectric layer is on the sealing layer between the metal lines.

In one embodiment, a method includes forming a transistor, forming a first intermetal dielectric layer above the transistor, forming a plurality of metal lines with a sealing layer covering at least a top of each metal line, forming a first intermetal dielectric sub-layer between the metal lines and on the sealing layer above the metal lines, and performing a CMP process on the first intermetal dielectric sub-layer including using the sealing layer as an etch stop layer to stop the CMP process.

In one embodiment, an integrated circuit includes a first intermetal dielectric layer, a first metal line on the first intermetal dielectric layer, and a second metal line on the first intermetal dielectric layer. The integrated circuit includes a sealing layer continuously covering top surfaces and sidewalls of the first and second metal lines and the top surface of the first intermetal dielectric layer between the first and second metal lines. The integrated circuit includes a second intermetal dielectric layer on the sealing layer above and between the first and second metal lines.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

The invention claimed is:

1. A method, comprising:
forming a transistor;
forming a first intermetal dielectric layer above the transistor;
forming a plurality of metal lines with a sealing layer covering at least a top of each metal line;
forming a first intermetal dielectric sub-layer between the metal lines and on the sealing layer above the metal lines; and
performing a CMP process on the first intermetal dielectric sub-layer including using the sealing layer as an etch stop layer to stop the CMP process.

2. The method of claim 1, wherein forming the metal lines and the sealing layer includes:
forming a metal stack on the first intermetal dielectric layer;
patterning the metal stack to form the metal lines on the first intermetal dielectric layer; and
forming the sealing layer on the tops and sidewalls of the metal lines and on the exposed surface of the first intermetal dielectric layer between the metal lines.

3. The method of claim 1, wherein forming the metal lines and the sealing layer includes:
forming a metal stack on the first intermetal dielectric layer;
forming the sealing layer on a top of the metal stack; and
patterning the sealing layer and the metal stack to form the plurality of metal lines with the sealing layer on the top of the metal lines.

4. The method of claim 1, wherein performing the CMP process includes:
performing a first CMP step corresponding to a timed CMP step; and
performing a second CMP step after the time CMP step including using the sealing layer as the etch stop,
and wherein the first CMP step includes using a first slurry, wherein the second CMP step includes using a second slurry different from the first etch chemistry.

5. The method of claim 1, wherein the first intermetal dielectric layer is silicon oxide.

6. The method of claim 1, comprising depositing a second intermetal dielectric sub-layer on the first intermetal dielectric sub-layer.

7. The method of claim 6, wherein the second intermetal dielectric sub-layer has a top surface that is substantially planar without CMP.

8. The method of claim 6, wherein the first intermetal dielectric sub-layer and the second intermetal dielectric sub-layer collectively form a second intermetal dielectric layer.

9. The method of claim 6, comprising:
exposing a top surface of one of the metal lines by forming a trench in the second intermetal dielectric sub-layer; and
forming a conductive via in the trench in contact with the top surface of the metal line.

10. The method of claim 6, wherein a first distance between a top surface of a first one of the metal lines and a top surface of the second intermetal dielectric sub-layer is substantially the same as a distance between a top surface of a second one of the metal lines and the top surface of the second intermetal dielectric sub-layer center, wherein the first one of the metal lines is in an integrated circuit near a center of a wafer, wherein the second one of the metal lines in a second integrated circuit near an edge of the wafer.

11. The method of claim 1, wherein the sealing layer is made of one of: silicon nitride, silicon carbonitride (SiCN), aluminum nitride (AlN), alumina (Al₂O₃), hafnium oxide (HfO₂), Hafnium alumino-oxide (HfₓAl_{y}O_{z}).

12. The method of claim 1, wherein the sealing layer has a thickness greater than or equal to 50 nm and less than or equal to 500 nm.

13. An integrated circuit, comprising:
a transistor;
a first intermetal dielectric layer above the transistor;
a plurality of metal lines on the first intermetal dielectric layer;
a sealing layer at least on top of the metal lines;
a second intermetal dielectric layer on the first intermetal dielectric layer and on the sealing layer.

14. The integrated circuit of claim 13, wherein the second intermetal dielectric layer includes:
a first intermetal dielectric sub-layer having a top surface substantially coplanar with a top surface of the sealing layer; and
a second intermetal dielectric sub-layer on the first intermetal dielectric sub-layer, and wherein a top surface of the second intermetal dielectric layer is substantially equidistant from a top of each of the metal lines.

15. The integrated circuit of claim 14, wherein the first and second intermetal dielectric sub-layers are of a same material.

16. The integrated circuit of claim 13, wherein the transistor is a GaN transistor.

17. The integrated circuit of claim 13, wherein:
the sealing layer continuously covers also sidewalls of the metal lines and a top surface of the first intermetal dielectric layer between the metal lines; and
the second intermetal dielectric layer is on the sealing layer between the metal lines.

18. An integrated circuit, comprising:
a first intermetal dielectric layer;
a first metal line on the first intermetal dielectric layer;
a second metal line on the first intermetal dielectric layer;
a sealing layer continuously covering top surfaces and sidewalls of the first and second metal lines and a top surface of the first intermetal dielectric layer between the first and second metal lines; and
a second intermetal dielectric layer on the sealing layer above and between the first and second metal lines.

19. The integrated circuit of claim 18, wherein the sealing layer has a thickness greater than or equal to 50 nm and less than or equal to 500 nm.

20. The integrated circuit of claim 18, comprising a plurality of transistors below the first intermetal dielectric layer.
